(19) United States
(12) Patent Application Publication
(10) Pub. No.: US 2019/0305143 A1
(43) Pub. Date: Oct. 3, 2019

(54) APPARATUSES AND METHODS FOR A VARIABLE CAPACITOR

(71) Applicant: QUALCOMM Incorporated, San Diego, CA (US)

(72) Inventors: Fabio Alessio MARINO, San Marcos, CA (US); Narasimhulu KANIKE, San Diego, CA (US); Qingqing LIANG, San Diego, CA (US); Francesco CAROBOLANTE, Carlsbad, CA (US); Paolo MENEGOLI, San Jose, CA (US)

(21) Appl. No.: 15/937,021

(22) Filed: Mar. 27, 2018

(51) Int. Cl. H01L 29/94; H01L 29/10; H01L 29/423; H01L 29/66

(52) U.S. Cl. CPC H01L 29/94; H01L 29/66189; H01L 29/42312; H01L 29/1095

(57) ABSTRACT

In certain aspects, a variable capacitor comprises a well having a first side and a second side, an N+ diffusion abutted the well at the first side, a P+ diffusion abutted the well at the second side, and an insulator on the well. The variable capacitor further comprises a gate plate on the insulator having a first gate segment and a second gate segment, wherein the first gate segment and the second gate segment are configured to have different work functions.

### BACKGROUND

### Field

Aspects of the present disclosure relate to the semiconductor structures, and more particularly, to apparatuses and manufacturing methods for improving the C-V characteristic linearity of a variable capacitor.

### Background

Capacitors are commonly used in many different types of alternating current (AC) circuits and radio frequency (RF) circuits. Capacitors are combined with inductors and other components to implement filters, duplexers, resonators, tuners, and other functions in these circuits. Electronic devices such as smart phones, tablets, laptop computers, and the like are now typically expected to use many different radio communication protocols and operate over a wide variety of frequencies, while at the same time being as small and inexpensive as possible. Variable capacitors have capacitance values that can be varied by applying voltage to their electrodes and have been widely used in high frequency circuits. Most of these circuits require good linearity of the capacitance value over the tuning range.

Although the linearity of the variable capacitors may be improved by using different circuit architectures or operation methods, those architectures or methods often come at the expense of design cost and with increased die area. Accordingly, it would be beneficial to provide apparatuses and manufacturing methods for improving the C-V characteristic linearity of variable capacitors at device processing level.

### SUMMARY

The following presents a simplified summary of one or more implementations to provide a basic understanding of such implementations. This summary is not an extensive overview of all contemplated implementations, and is intended to neither identify key nor critical elements of all implementations nor delineate the scope of any or all implementations. The sole purpose of the summary is to present concepts relate to one or more implementations in a simplified form as a prelude to a more detailed description that is presented later.

In one aspect, a variable capacitor comprises a well having a first side and a second side, an N+ diffusion abutted the well at the first side, a P+ diffusion abutted the well at the second side, and an insulator on the well. The variable capacitor further comprises a gate plate on the insulator having a first gate segment and a second gate segment, wherein the first gate segment and the second gate segment are configured to have different work functions

In another aspect, a variable capacitor having a first side and a second side, wherein the well comprises a first well segment having N doping and a second well segment having P doping, an N+ diffusion abutted the well at the first side, a P+ diffusion abutted the well at the second side, an insulator on the well, and a gate plate on the insulator.

In another aspects, a method comprises forming a well having a first side and a second side, forming an N+ diffusion abutted the well at the first side, forming a P+ diffusion abutted the well at the second side, forming an insulator on the well, and forming a gate plate on the insulator having a first gate segment and a second gate segment, wherein the first gate segment and the second gate segment are configured to have different work functions.

To accomplish the foregoing and related ends, one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the described implementations are intended to include all such aspects and their equivalents.

### BRIEF DESCRIPTION OF THE DRAWINGS

FIG. 1 illustrates an example variable capacitor according to certain aspects of the present disclosure.

FIG. 2 illustrates a top-down view of an example variable capacitor according to certain aspects of the present disclosure.

FIG. 3 illustrates C-V characteristics of variable capacitors according to certain aspects of the present disclosure.

FIG. 4 illustrates an exemplary variable capacitor according to certain aspects of the present disclosure.

FIG. 5 illustrates an alternative exemplary variable capacitor according to certain aspects of the present disclosure.

FIG. 6 illustrates still another alternative exemplary variable capacitor according to certain aspects of the present disclosure.

FIG. 7 illustrates still another alternative exemplary variable capacitor according to certain aspects of the present disclosure.

FIG. 8 illustrates an exemplary method for making a variable capacitor according to certain aspects of the present disclosure.

### DETAILED DESCRIPTION

The detailed description set forth below, in connection with the appended drawings, is intended as a description of various aspects and is not intended to represent the only aspects in which the concepts described herein may be practiced. The detailed description includes specific details for the purpose of providing an understanding of the various concepts. However, it will be apparent to those skilled in the art that these concepts may be practiced without these specific details. In some instances, well-known structures and components are shown in block diagram form in order to avoid obscuring such concepts.

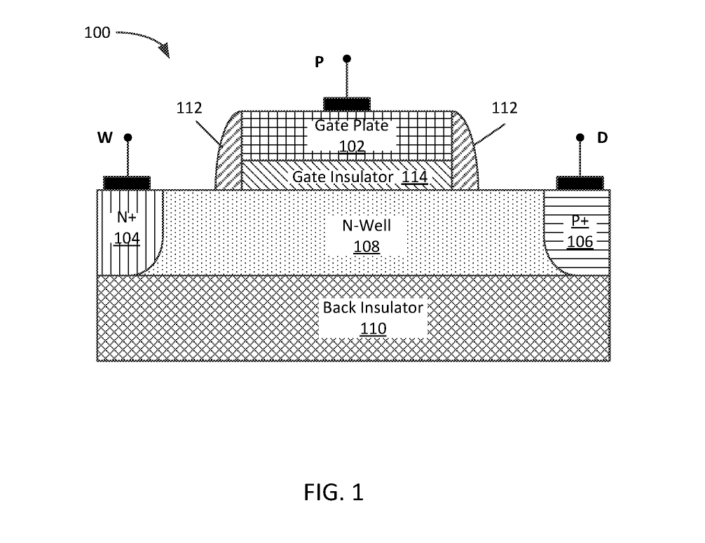

A variable capacitor is a three-terminal semiconductor capacitor where the capacitance between the two main terminals P (coupled to a polysilicon or metal gate plate) and W (coupled to a well, e.g., N- or P-Well, through an N+ diffusion or P+ diffusion) is varied by changing a voltage between a displacement terminal D (formed by a P+ or N+ diffusion) and one of the two main terminals, W. FIG. 1 illustrates an example variable capacitor according to certain aspects of the present disclosure. The variable capacitor 100 comprises two plates: the first plate is formed by a gate plate 102 and the second plate is formed by an N-Well 108. The variable capacitor 100 further comprises three terminals: a first main terminal P coupled to the gate plate 102, a second main terminal W coupled to an N+ diffusion 104, which further abuts and couples to the N-Well 108 at one side, and a displacement terminal D coupled to a P+ diffusion 106, which also abuts the N-Well 108 at another side. A gate insulator 114 lies between the gate plate 102 and the N-Well 108. The variable capacitor 100 is implemented in an SOI process. A layer of back insulator 110 is at the bottom of the N-Well 108 to provide isolation to neighboring devices. Insulating spacers 112 isolate the gate plate 102 from the N+ diffusion 104 and the P+ diffusion 106.

While the second plate of the variable capacitor 100 is an N-Well in FIG. 1, a P-Well may be used, too. If a P-Well is used as the second plate, then the second terminal W is coupled to a P+ diffusion, while the displacement terminal D is coupled to an N+ Diffusion.

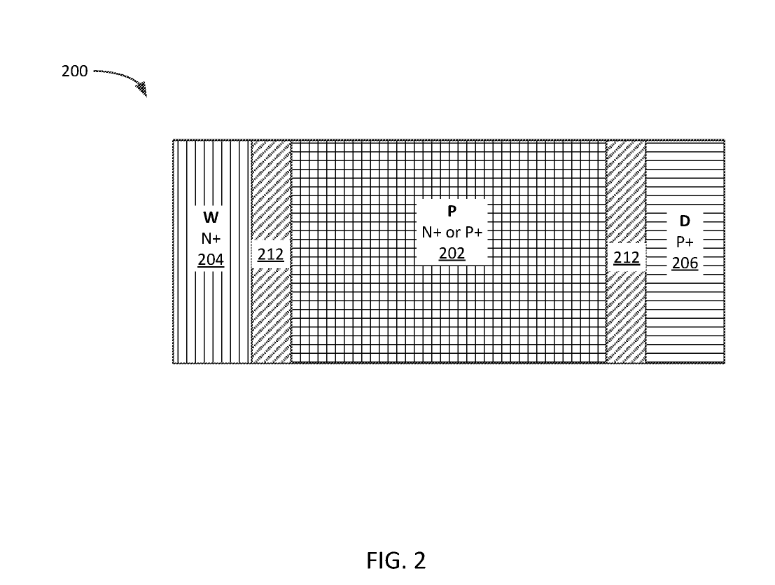

FIG. 2 illustrates a top-down view of an example variable capacitor according to certain aspects of the present disclosure. Like the variable capacitor 100, the variable capacitor 200 comprises two main terminals, a terminal P coupled to a polysilicon gate plate 202 and a terminal W coupled to an N+ diffusion 204 (which couples to an N-well (not shown)). The capacitance of the variable capacitor 200 is varied by changing a voltage between a displacement terminal D coupled to a P+ diffusion 206 and one of the two main terminals, W. The second plate of the variable capacitor, the N-Well, is below the gate plate 202 and is not shown. Although the gate plate 202, the N+ diffusion 204, and the P+ diffusion 206 are shown to be in rectangle shape, they can be in other shapes, too. Typically, the gate plate 202 may be N+ polysilicon or P+ polysilicon. Between the gate plate 202 and the N+ diffusion 204 or the P+ diffusion 206 is an insulating spacer 212.

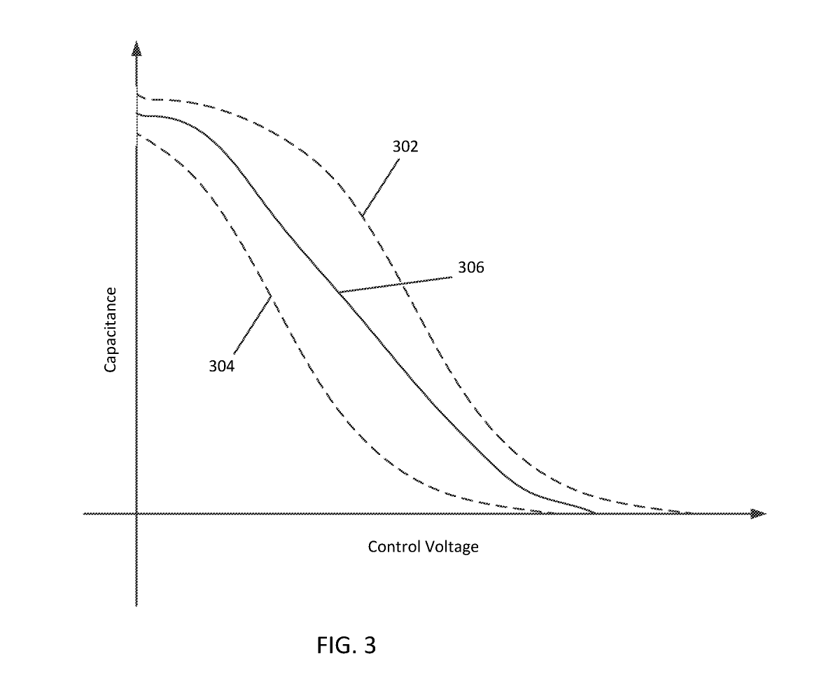

FIG. 3 illustrates C-V characteristics of variable capacitors according to certain aspects of the present disclosure. Line 302 represents C-V characteristic of an N+ polysilicon gate plate variable capacitor, line 304 represents C-V characteristic of a P+ polysilicon gate plate variable capacitor, and line 306 represents C-V characteristic for averaging a N+ polysilicon gate plate variable capacitor and a P+ polysilicon gate plate variable capacitor. Because of work function difference, N+ polysilicon gate plate variable capacitor C-V line 302 shifts right as compared to the P+ polysilicon gate plate variable capacitor line 304. By averaging the capacitances of both the N+ polysilicon gate plate variable capacitor and the P+ polysilicon gate plate variable capacitor, the linearity of C-V curve line 306 is better than either line 302 or line 304. Accordingly, if the capacitances of two or more variable capacitors with shifted gate work functions are added together, the overall C-V curve has better linearity.

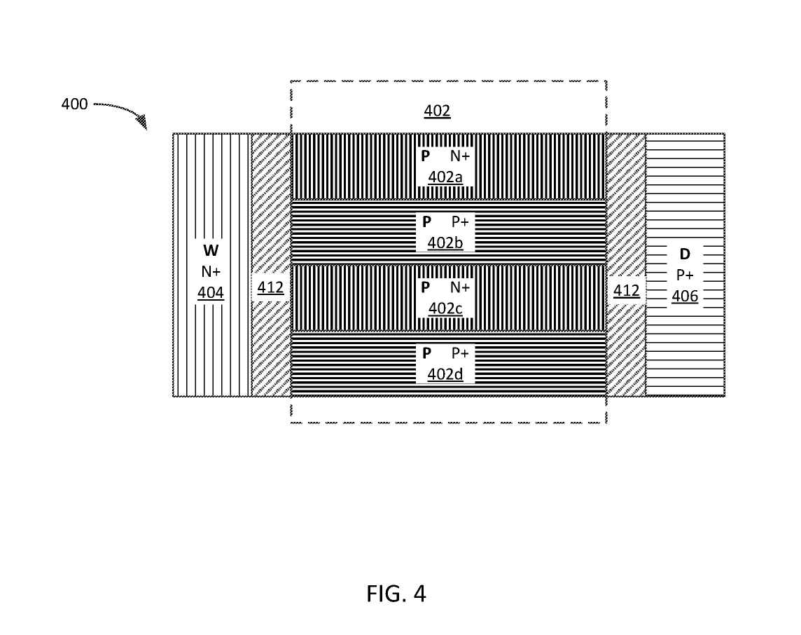

FIG. 4 illustrates a top-down view of an exemplary variable capacitor according to certain aspects of the present disclosure. Like the variable capacitor 100 or 200, the variable capacitor 400 comprises two main terminals: a terminal P coupled to a gate plate 402 and a terminal W coupled to an N+ diffusion 404. The capacitance of the variable capacitor 400 is varied by changing a voltage between a displacement terminal D coupled to a P+ diffusion 406 and one of the two main terminals, W. The second plate of the variable capacitor, an N-Well, is below the gate plate 402 and is not shown. The N+ diffusion 404 abuts the N-well at one side to couple the terminal W to the N-Well. The P+ diffusion 406 abuts the N-Well at another side. Although the gate plate 402, the N+ diffusion 404, and the P+ diffusion 406 are shown to be in rectangle shape, they can be in other shapes, too. Between the gate plate 402 and the N+ diffusion 404 or the P+ diffusion 406 is an insulating spacer 412.

The gate plate 402 comprises a plurality of gate segments 402a-402d with different work functions. Each of the gate segments 402a-402d abuts another gate segments 402a-402d. All the gate segments 402a-402d together form the gate plate 402 and couple to the terminal P (e.g., through a silicide layer). The variable capacitor 402 therefore may be equivalent to a plurality of parallelly connected sub-capacitors, each formed by a gate segment 402a-402d and the N-Well. The overall capacitance of the variable capacitor 400 is the sum of the sub-capacitors' capacitances. Because of the averaging effect of C-V characteristics of the sub-capacitors, the linearity of C-V characteristics of the variable capacitor 400 is better than the variable capacitor 200 where the gate plate is either pure P+ doped or N+ doped.

The work function difference is created by doping polysilicon gate plate to either P+ or N+. For example, the gate segments 402a and 402c are doped N+ while the gate segments 402b and 402d are doped P+. The number of gate segments is shown to be 4 in FIG. 4 but may be more or fewer. The size of each gate segment may be the same or different. The total gate segment size for N+ diffusion is preferably same as the total size for P+ diffusion but is not required.

For a metal gate plate where P+ or N+ doping may not be effective to generate work function difference, the work function difference may be created by using different gate materials to create P-type gate segments and N-type gate segments. For example, TiN may be used to tune the work function to be P-type while TiAl may be used to tune the work function toward N-type.

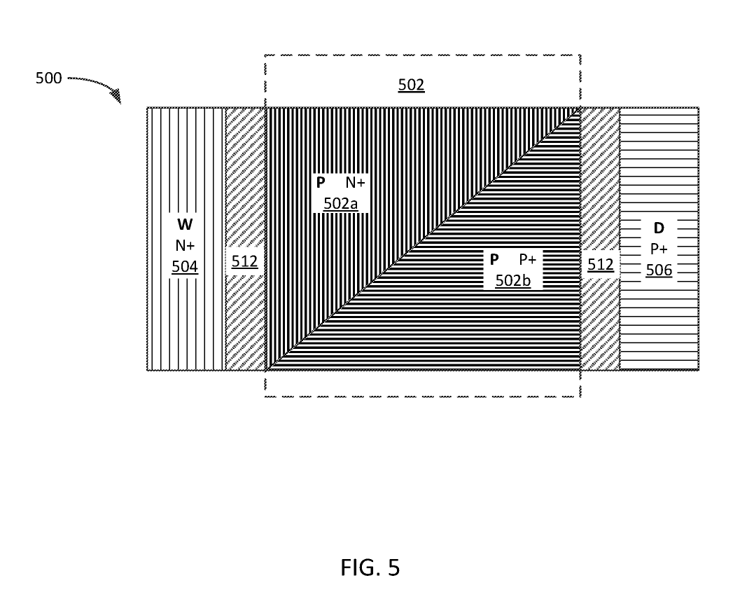

In addition to the arrangement of gate segments illustrated in FIG. 4, other shapes or arrangements are possible. FIG. 5 illustrates an alternative exemplary variable capacitor according to certain aspects of the present disclosure. Like the variable capacitor 400, the variable capacitor 500 comprises two main terminals, a terminal P coupled to a gate plate 502 and a terminal W coupled to an N+ diffusion 504. The capacitance of the variable capacitor 500 is varied by changing a voltage between a displacement terminal D coupled to a P+ diffusion 506 and one of the two main terminals, W. The second plate of the variable capacitor, an N-Well, is below the gate plate 502 and is not shown. The N+ diffusion 504 abuts the N-well at one side to couple the terminal W to the N-Well. The P+ diffusion 506 abuts the N-Well at another side. Although the gate plate 502, the N+ diffusion 504, and the P+ diffusion 506 are shown to be in rectangle, they can be in other shapes, too. Between the gate plate 502 and the N+ diffusion 504 or the P+ diffusion 506 is an insulating spacers 512.

The variable capacitor 500 also comprise a plurality of gate segments 502a-502b with different work functions. Each of the gate segments 502a-502b abuts another gate segments 502a-502b. All the gate segments 502a-502b together form the gate plate 502 and couple to the terminal P (e.g., through a silicide layer). The different work functions may be formed with different types of doping for a polysilicon gate plate or different materials for a metal gate plate. Unlike the variable capacitor 400 where the gate segments are in rectangle shape, the segments 502a-502b are in triangle shape. The number of gate segments may be 2 as illustrated in FIG. 5 or may be more, and they may be arranged in different patterns.

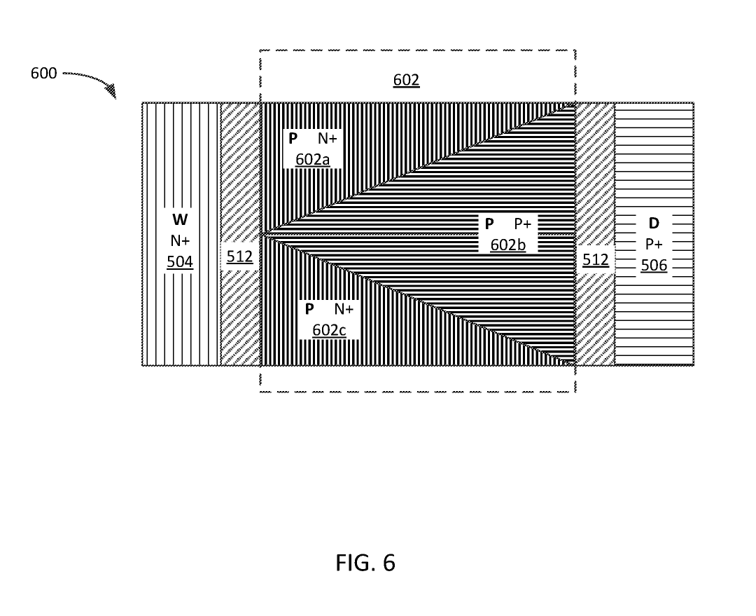

FIG. 6 illustrates yet another alternative exemplary variable capacitor according to certain aspects of the present disclosure. The variable capacitor 600 is similar to the variable capacitor 500 except the gate segment arrangement for the gate plate 602. The gate plate 602 comprises N+ type work function gate segments 602a and 602c and P+ type work function gate segment 602b. Other segmentation patterns are possible.

While the second plates of the variable capacitor 400 in FIG. 4, 500 in FIGS. 5, and 600 in FIG. 6, are N-Well, a P-Well may be used for each case. If a P-Well is used as the second plate, then the second terminal W is coupled to a P+ diffusion, while the displacement terminal D is coupled to an N+ Diffusion.

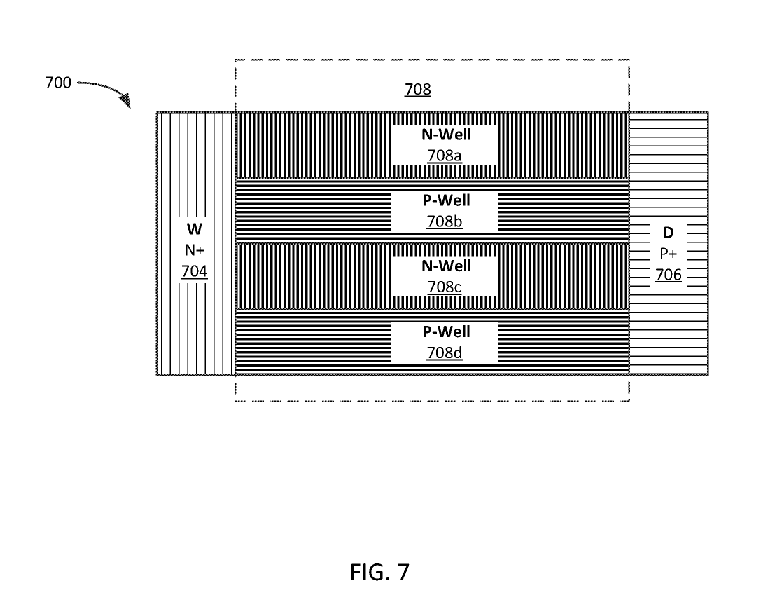

Alternatively, the segmentation may be used in the active region instead of the gate plate. FIG. 7 illustrates another alternative exemplary variable capacitor according to certain aspects of the present disclosure. The variable capacitor 700 comprises two main terminals, a terminal P coupled to a gate plate (not shown) and a terminal W coupled to an N+ diffusion 704. The capacitance of the variable capacitor 700 is varied by changing a voltage between a displacement terminal D coupled to a P+ diffusion 706 and one of the two main terminals, W. The gate plate, the insulating spacer, and the gate insulating layer are not shown so that the second plate of the variable capacitor, a well 708, can be seen. As can be seen from FIG. 7, the N+ diffusion 704 abuts the N-well 708 at one side to couple the terminal W to the N-Well 708. The P+ diffusion 706 abuts the N-Well 708 at another side.

The well plate 708 comprises a plurality of well segments 708a-708d with different doping types. Each of the well segments 708a-708d abuts another well segments 708a-708d. If a positive voltage is applied on the gate plate (not shown), A depletion or inversion happens at the surface of P-Well. Thus, at the surface, all the well segments 708a-708d are electrically coupled and together form the second plate 708 and couples to N+ diffusion 704. The variable capacitor 700 therefore may be equivalent to a plurality of parallelly connected sub-capacitors, each formed by the gate plate (not shown) and a well segment 708a-708d. The overall capacitance of the variable capacitor 700 is the sum of the capacitances of the sub-capacitors.

Similar to C-V characteristics illustrated in FIG. 3, the C-V characteristic for a pure N-Well plate variable capacitor shifts right compared to the C-V characteristic for a pure P-Well plate variable capacitor. By interleaving the P-Well segments and N-Well segments, due to the averaging effect of C-V characteristics of the P-well plate sub-capacitors and the N-Well plate sub-capacitors, the linearity of C-V characteristics of the variable capacitor 700 is better than the variable capacitor 200 where the well is pure N type or pure P type.

By interleaving the N-Well and the P-Well, a depletion region is formed between an interface of an N-Well and a P-Well, such as the interface between N-Well segment 708a and the P-Well segment 708b, the interface between the N-Well 708c segment and the P-Well segment 708b, and the interface between the N-Well segment 708c and the P-Well segment 708d. Through the depletion regions in multiple locations, the variable capacitor 700 may have faster response to the control voltage, which applies to the displacement terminal, D, and couples to each of the P-Well segments 708b and 708c through P+ diffusion 706.

Like the gate plate that may have different shapes and different patterns, the well plate 708 may similarly have different shapes and different patterns.

In addition, the segmentation is not limited to gate plate only or well plate only. The segmentation can be applied to both gate plate and well plate simultaneously. And the gate plate and the well plate may use different segment sizes, shapes, or patterns. Moreover, the segmentation schemes illustrated in FIGS. 4-7 are applicable for a variable capacitor manufactured in bulk process as well as SOI process or any other suitable technologies.

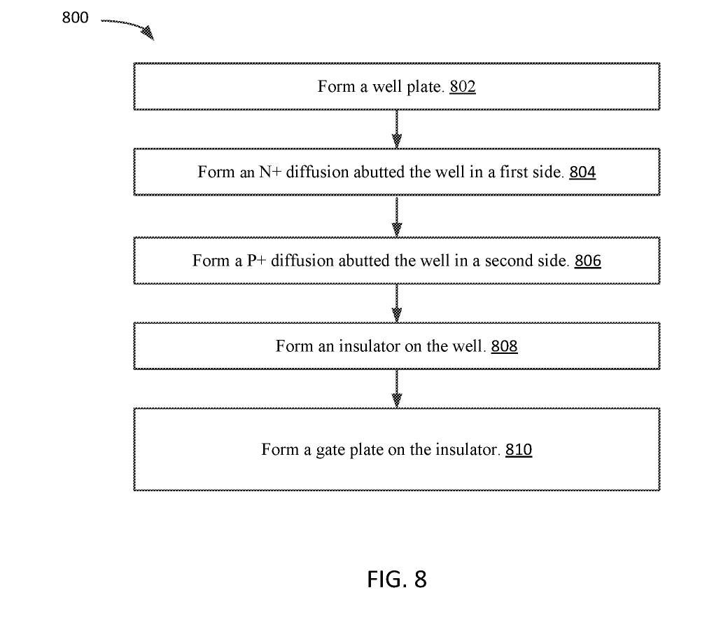

FIG. 8 illustrates an exemplary method for making a variable capacitor according to certain aspects of the present disclosure. At 802, a well plate is formed. The well plate may be an N-Well or a P-Well (e.g., N-Well 108). The well plate may be segmented with a plurality of well segments having different doping types, such as either N doping or P doping. At 804, an N+ Diffusion is formed abutting the well at a first side (e.g., N+ diffusion 104, 204, 404, 504, 604, or 704). At 806, a P+ diffusion is formed abutting the well at a second side (e.g., the P+ diffusion 106, 206, 406, 506, 606, or 706). If the well is N-Well, N+ diffusion serves as one of two terminals of the variable capacitor, while the P+ diffusion serves as the displacement terminal. If the well is P-Well, P+ diffusion serves as one of two terminals of the variable capacitor, while the N+ diffusion serves as the displacement terminal. At 808, an insulator is formed on the well (e.g., the gate insulator 114). Then at 810, a gate plate is formed on the insulator (e.g., the gate plate 102, 202, 402, 502, 602). The gate plate may be segmented with a plurality of gate segments having different work functions. The different work functions may be formed using different doping types, such as N+ doping (e.g., the gate segments 402a, 402c, 502a, 602a, 602c) or P+ doping (e.g., the gate segments 402b, 402d, 502b, 602b) for different gate segments if the gate plate is polysilicon. For a metal gate plate, different materials may be used to tune the work function. For example, TiN may be doped to the gate segments to tune the work function to P+ type while the TiAl may be doped to tune the work function to be N+ type.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

1-14. (canceled)

15. A variable capacitor, comprising:
a well having a first side and a second side, wherein the well comprises a first well segment having N doping and a second well segment having P doping, wherein the well is configured to be the first plate of the variable capacitor;
an N+ diffusion abutted the first well segment and the second well segment at the first side;
a P+ diffusion abutted the first well segment and the second well segment at the second side;
an insulator on the well; and
a gate plate on the insulator and over the first well segment and the second well segment, wherein the gate plate is configured to be the second plate of the variable capacitor.

16. The variable capacitor of claim 15, wherein the first well segment and the second well segment are in rectangle shape.

17. The variable capacitor of claim 15, wherein the first well segment and the second well segment are triangle shape.

18. The variable capacitor of claim 15, wherein the first well segment and the second well segment have different sizes.

19. The variable capacitor of claim 15, wherein the first well segment abuts the second well segment.

20-30. (canceled)

31. The variable capacitor of claim 15, wherein the gate plate comprises a first gate segment and a second gate segment, wherein the first gate segment and the second gate segment are configured to have different work functions.

32. The variable capacitor of claim 31, wherein the first gate segment is doped N type and the second gate segment is doped P type.

33. The variable capacitor of claim 31, wherein the first gate segment comprises different materials from the second gate segment.

34. The variable capacitor of claim 31, wherein the first gate segment and the second gate segment are in rectangle shape.

35. The variable capacitor of claim 31, wherein the first gate segment and the second gate segment have different sizes.

36. The variable capacitor of claim 31, wherein the first gate segment abuts the second gate segment.
